(19) United States
(12) Patent Application Publication
(10) Pub. No.: US 2024/0203935 A1
(43) Pub. Date: Jun. 20, 2024

(54) METHOD OF EMBEDDING A BARE DIE IN A CARRIER LAMINATE

(71) Applicant: Infineon Technologies AG, Neubiberg (DE)

(72) Inventors: Toni SALMINEN, München (DE); Mahadi-Ul HASSAN, Regensburg (DE); Nagarajan PALAVESAM, Fürstenfeldbruck (DE)

(73) Assignee: Infineon Technologies AG, Neubiberg (DE)

(21) Appl. No.: 18/528,237

(22) Filed: Dec. 4, 2023

(30) Foreign Application Priority Data
Dec. 19, 2022 (DE) 10 2022 133 833.9

(51) Int. Cl. H01L 23/00; H01L 21/56

(52) U.S. Cl. CPC H01L 24/82; H01L 21/568; H01L 24/19; H01L 24/20; H01L 24/24; H01L 2224/19; H01L 2224/211; H01L 2224/215; H01L 2224/24155; H01L 2224/244; H01L 2224/245; H01L 2224/82106; H01L 2924/01013; H01L 2924/01029

(57) ABSTRACT

A method of embedding a bare die in a carrier laminate is provided. The method includes providing the bare die including a metal layer on a front side of the bare die or on a back side of the bare die opposite the front side. A layer is formed over the metal layer. The bare die is mounted in a recess of the carrier laminate with the layer facing an opening of the recess. The recess is filled with a dielectric material. A portion of the dielectric material that is on the layer is removed. A metal structure is deposited over at least a portion of the layer and at least a portion of the carrier laminate.

### CROSS-REFERENCE TO RELATED APPLICATION

This Utility Patent Application claims priority to German Patent Application No. 10 2022 133 833.9 filed Dec. 19, 2022, which is incorporated herein by reference.

### TECHNICAL FIELD

Various embodiments relate generally to a method of embedding a bare die in a carrier laminate.

### BACKGROUND

In current state of the art methods for embedding a bare die in a carrier laminate, dry etching (in vacuum) is used for opening the die backside area. The process is not well mastered by many PCB manufacturers and requires specific manufacturing equipment. Today, dry-etching is for example used for chip-embedding for removing organic material to reach the chip backside metallization for further printed circuit board (PCB) processing.

Laser drilling is another technique that is used for gaining access to the chip backside metallization, but it does not provide full-area opening possibility similar to dry plasma etch. Therefore, for further product thermal and electrical behavior, it is expected that an embedded die, a backside metallization of which was partially exposed via laser, will perform less efficiently than the full-area contact that is formed by, for example, a metal CONNECTION by Cu-plating

### SUMMARY

A method of embedding a bare die in a carrier laminate is provided. The method includes providing the bare die including a metal layer on a front side of the bare die or on a back side of the bare die opposite the front side. A layer is formed over the metal layer. The bare die is mounted in a recess of the carrier laminate with the layer facing an opening of the recess. The recess is filled with a dielectric material. A portion of the dielectric material that is on the layer is removed (e.g., by electroless plating, sputtering or Atomic Layer Deposition (ALD)″). A metal structure is deposited over at least a portion of the layer and at least a portion of the carrier laminate.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A to 10A illustrate a method of embedding a bare die in a carrier laminate according to various embodiments;

FIGS. 1B to 10B illustrate a method of embedding a bare die in a carrier laminate according to various embodiments;

FIGS. 1C to 10C illustrate a method of embedding a bare die in a carrier laminate according to various embodiments;

FIGS. 1D to 10D illustrate a method of embedding a bare die in a carrier laminate according to prior art;

FIG. 11A illustrates alternative configurations of the bare die for use in the method of FIGS. 1A to 10A;

FIG. 11B illustrates alternative configurations of the bare die for use in the method of FIGS. 1B to 10B;

FIG. 11C illustrates alternative configurations of the bare die for use in the method of FIGS. 1C to 10C;

FIG. 12 shows a flow diagram of a method of embedding a bare die in a carrier laminate in accordance with various embodiments; and

FIG. 13 shows a carrier-embedded die in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

In various embodiments, bare dies (dies or chips for short) may be delivered with a dielectric material, for example a resist, covering the back and/or front side metal layer (also referred to as metallization or contact pad), or with a thick back and/or front side metallization, which may be achieved by providing an additional metal layer over (e.g., on) the back and/or front side metal layer.

In this context, “thick” is to be understood as at least as thick as the metal layer that is typically provided on a chip surface, for example as the chip contact pad.

The dielectric or metal material, e.g. layer, may have at least the same thickness as the metal layer. The thick dielectric or metal layer may be up to approximately 15 times as thick as the metal layer.

In various embodiments, the bare dies may be provided with a thin metal layer, for example with a layer of sputtered material, thin-film or nano-coating to create a pre-seed layer on the chip surface. The thin layer may cover the full surface or may be selectively applied, for example to the metal layer(s), e. g., the front- and/or backside metallizations only.

The layer (e. g., the thick dielectric layer, thick metal layer or thin metal layer) may be formed during a front end of line process, for example during wafer processing. In other words, the layer may already be present on the bare die when the die is provided for PCB mounting/processing.

The thin seed layer may be plated to form a thicker layer.

In various embodiments, it may be beneficial as compared with prior art that standard PCB manufacturing processes like grinding or wet etching may be used. This may result in a much faster, simplified and cost effective chip embedding or inlay embedding processing at a PCB manufacturer. In particular, time consuming and/or expensive non-standard techniques like vacuum plasma etching, sputtering and/or high-density μ Via laser drilling may be avoided or limited to a minimum.

In various embodiments, in particular those with the additional thick dielectric or metal layer, the die would be better protected from mechanical damage during handling, e.g. during die placement.

In addition, tolerances on die positioning may be looser, since the area that is removed for contacting the die is defined by the die itself.

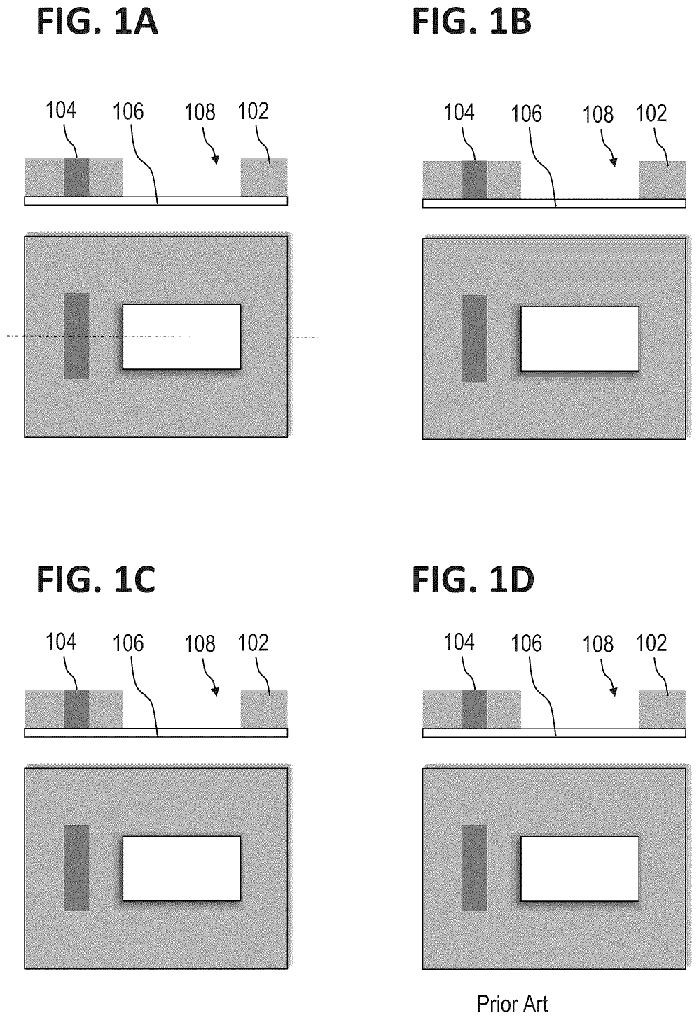

A first method of embedding a bare die in a carrier laminate in accordance with various embodiments is illustrated in FIG. 1A to 10A.

A second method of embedding a bare die in a carrier laminate in accordance with various embodiments is illustrated in FIG. 1B to 10B.

A third method of embedding a bare die in a carrier laminate in accordance with various embodiments is illustrated in FIG. 1C to 10C.

Those methods, and in particular their similarities and differences, will be explained in the following. Whenever appropriate, the methods according to the embodiments will be compared to a method of embedding a bare die in a carrier laminate of the prior art as shown in FIG. 1D to 10D.

In each of FIGS. 1A to 10D, the bottom panel shows a schematic top view of a carrier-embedded die 1300 at various stages of processing, and the top panel shows schematically a horizontal cross-section through a center of the carrier-embedded die 1300. The location of the cross section is indicated only in FIG. 1A as a dot-dashed horizontal line.

A carrier laminate 102 having a recess 108 may be provided. Examples of this are shown in FIG. 1A to 1C. The carrier laminate 102 and the recess 108 formed therein may be similar or identical to the prior art.

The carrier laminate 102 may for example include or consist of any kind of carrier material that is typically used for a carrier laminate 102, for example a PCB laminate (e.g. FR4, BT laminate). The carrier laminate 102 may include or consist of a dielectric material that can be either fully cured (e.g., Copper Clad Laminate, CCL) or B-stage cured (PrePreg). The carrier laminate 102 may be pre-cut to form the cavity where the object (i.e., a bare die 220) is to be embedded to obtain a better topological fit for lamination and further laminate substrate processing.

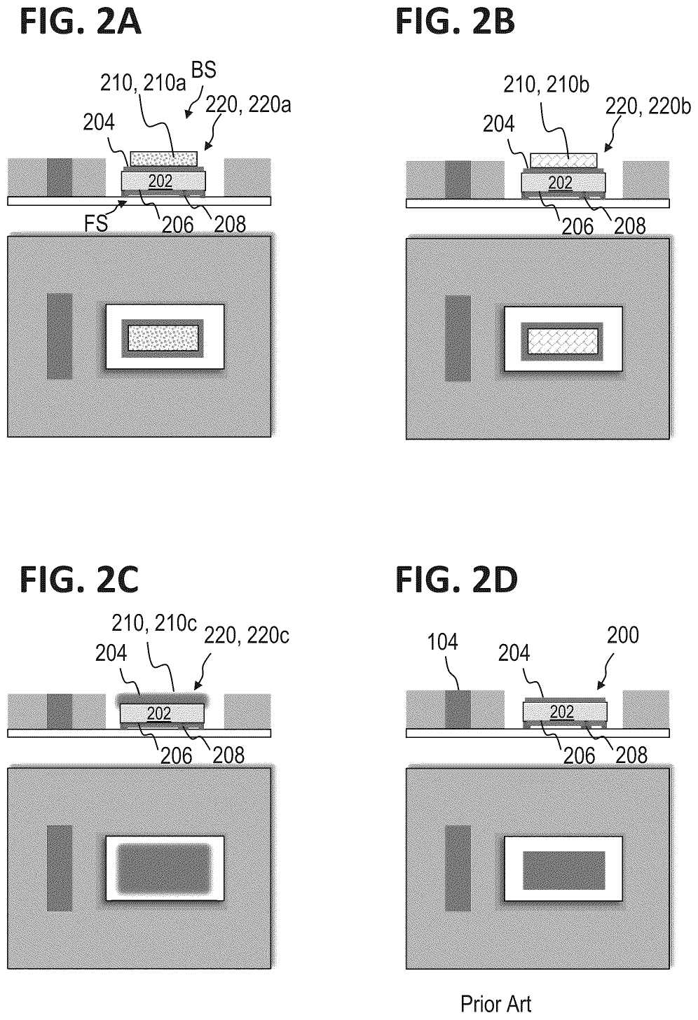

The recess 108 may be formed as a through-hole. In order to allow the placement of the die 220 in the recess 108, in particular in the case of a through-hole, a temporary carrier 106 may be attached to the bottom of the carrier laminate 102. In other embodiments, the recess 108 may extend only partially through the carrier laminate 102 (not shown). In such a case, processing from both sides of the carrier laminate 102 may be required in a case that the die 220 comprises contact pads on both opposite sides (for details on the die, see the description in context with FIGS. 2A to 2C).

Through-contacts 104 extending through the carrier laminate 102 from a top of the carrier laminate 102 to a bottom of the carrier laminate 102 may be formed in various embodiments, for example vias or other types of through-contacts 104. But even though all the figures show the through-contact 104, the carrier laminate 102 of various embodiments may be free from the through-contact 104.

The method of embedding the bare die 220 in the carrier laminate 102 in accordance with various embodiments includes providing the bare die 220 including a metal layer 206 or 204, respectively, on a front side FS of the bare die 220 or on a back side BS of the bare die 220 opposite the front side FS.

The bare die 220 may be a semiconductor die that forms an electronic component or includes an integrated circuit. The die 220 may be provided with a plurality of die contacts for electrically contacting the electronic component or the integrated circuit, respectively. In a case where a plurality of die contacts 204 or 206, respectively, is provided on the same side (like, e.g., the plurality of die contacts on the front side FS of the die 220 shown in FIGS. 2A to 2C), an electrically insulating material 208 may be provided between the respective die contacts 204 or 206, respectively. The metal layer(s) 204, 206 may form or electrically contact the die contacts and are therefore also referred to as chip contact pads, die contact pads or contact pads. Another term for the metal layer(s) 204, 206 is chip metallization. In a case where the die 220 has a control chip contact and at least one controlled chip contact, the front side FS may be defined to to be the side having the control contact.

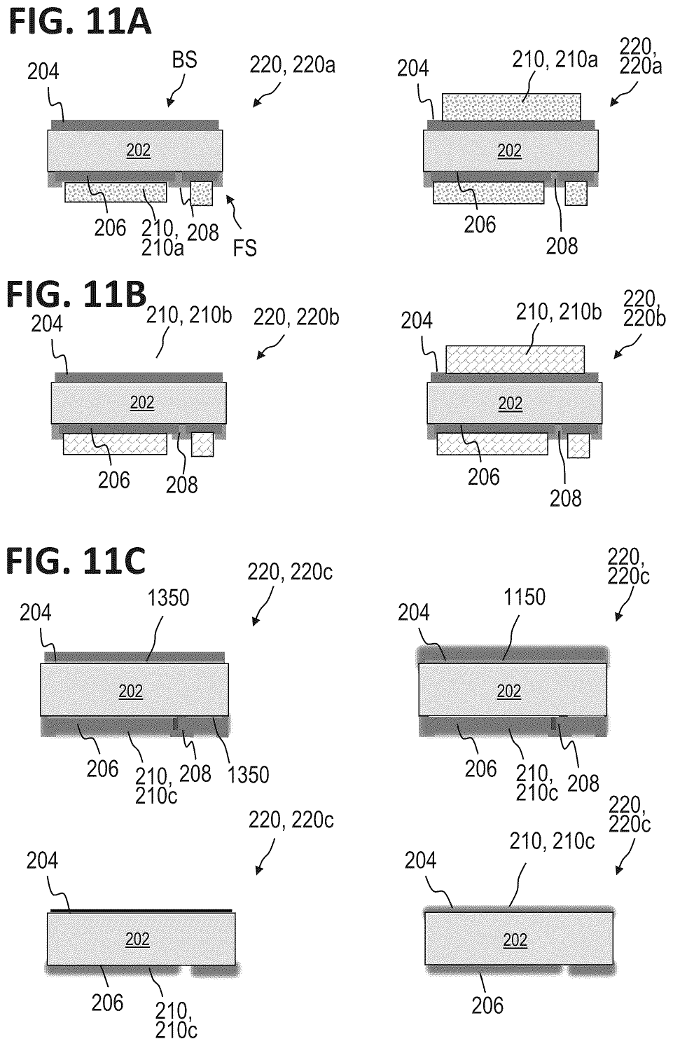

In various embodiments, a passivation layer 1150 (shown only, in an exemplary fashion, in FIG. 11C and formed essentially as known in the art) may be provided between the semiconductor material and the metal layer 204, 206.

The method of embedding the bare die 220 in the carrier laminate 102 in accordance with various embodiments further includes forming a layer 210 over the metal layer 204, 206.

Three different types of layers 210 are provided in accordance with various embodiments:

Option A (illustrated in FIGS. 1A to 10A) has a (thick) dielectric layer 210, 210a. In the exemplary embodiment of FIG. 2A to 10A, the layer 210, 210a is formed over the metal layer 204 on the back side BS of the die 220, 220a. However, as illustrated in FIG. 11A, other embodiments may include the dielectric layer 210, 210a only on the front side FS of the die 220, 220a (shown on the left side of FIG. 11A) or on both, the front side FS and the back side BS of the die 220, 220a (shown on the right side of FIG. 11A).

The dielectric layer 210, 210a may for example include or consist of a resist material (which may be easily removable using photoprocessing, e.g. light development and decomposition) or a different dielectric material that is suitable for PCB processing and easily removable by wet etching and/or laser ablation.

The dielectric layer 210, 210a may have a thickness in a range from about 2 μum to about 30 μm, for example from about 5 μm to about 25 μm, for example from about 10 μm to about 20 μm.

Option B (illustrated in FIGS. 1B to 10B) has a (thick) metal layer 210, 210b. In the exemplary embodiment of FIG. 2B to 10B, the layer 210, 210b is formed over the metal layer 204 on the back side BS of the die 220, 220b. However, as illustrated in FIG. 11B, other embodiments may include the metal layer 210, 210b only on the front side FS of the die 220, 220b (shown on the left side of FIG. 11B) or on both, the front side FS and the back side BS of the die 220, 220b (shown on the right side of FIG. 11B).

The metal layer 210, 201b may for example include or consist of copper or a copper alloy, aluminum or an aluminum alloy, or any other metal that is suitable for PCB processing.

The thick metal layer 210, 210b may have a thickness in a range from about 2 μm to about 30 μm, for example from about 5 μm to about 25 μm, for example from about 10 μm to about 20 μm.

Option C (illustrated in FIGS. 1C to 10C) has a (thin) metal layer 210, 210c. For visual distinction from the thick metal layer 210, 210b, the thin metal layer 210, 201c is shown in FIGS. 1C to 10C as a shaded “glow” that has no physical meaning.

The (thin) metal layer 210, 210c may for example be formed by or include a sputtered material, a thin-film or a nano-coating to create a pre-seed layer on the surface of the metal layer 210, 210c, and optionally also on a surface of the semiconductor material of the die 220, 220c, and on the surface of the insulating material 208 surface. In other words, the (thin) metal layer 210, 210c may be either applied to fully cover the die front side FS and/or back side BS surface, or to selectively cover only the metal layer(s) 210, 210c.

The thin metal layer 210, 210c, which may be a pre-seed layer, may have a thickness in a range from about 1 nm to about 2 μm, for example from about 5 nm to about 10 μm, for example from about 10 nm to about 1 μm.

The die 200 according to the prior art shown in FIG. 2D may include only the at least one metal layer 204, without the layer 210.

In the exemplary embodiment of FIG. 2C to 10C, the layer 210, 210c is formed over the metal layer 204 on the back side BS of the die 220, 220c. However, as illustrated in FIG. 11C, other embodiments may include the metal layer 210, 210c only on the front side FS of the die 220, 220b (shown on the left side of FIG. 11C) or on both, the front side FS and the back side BS of the die 220, 220b (shown on the right side of FIG. 11C).

In various embodiments, the bare die 210 may be arranged in the recess 108 of the carrier laminate 102 with the layer 210 facing an opening of the recess 108 (in other words, away from the temporary carrier 106).

In a case where both sides (FS and BS) of the die 220 may have the layer 210 formed, the side of the die 220 to be arranged on the temporary carrier 106 may be selected as suitable for the application, and the further processing may include, in addition to the processes described below, which focus on a processing of the carrier-embedded die from a top as presented in FIG. 2A to 10C, a processing from the bottom of the carrier-embedded die (e.g., after a removal of the temporary carrier 106). In such a case, the processing may, when suitable, be performed simultaneously from both sides of the carrier-embedded die. Alternatively, the top side and the bottom side (or vice versa) may be processed consecutively.

In the embodiments shown in FIG. 2A and 2B, a total thickness of the die 220, including the layer 210, may be larger than a depth of the recess and, respectively, than a thickness of the carrier laminate 102. As a consequence, the layer 210 may protrude from the recess.

In the embodiments shown in FIGS. 2A and 2B, a total thickness of the die 220, 220a, 220b, including the layer 210, 210a, 210b, respectively, may be larger than a depth of the recess 108, and larger than a thickness of the carrier laminate 102. As a consequence, the layer 210 may protrude from the recess 108.

In the embodiment shown in FIG. 2C, a total thickness of the die 220, 220c, including the layer 210, 210c, may be approximately the same as (for example slightly smaller than) the depth of the recess 108, and approximately the same as (for example slightly smaller than) the thickness of the carrier laminate 102. As a consequence, a surface of the layer 210 may be more or less flush with (optionally slightly lower than) a surface of the carrier laminate 102 adjacent to an opening of the recess 108.

In the prior art, the die 200 is typically substantially thinner than a depth of the recess 108.

The method of embedding the bare die 220 in the carrier laminate 102 in accordance with various embodiments further includes filling the recess 108 with a dielectric material 330. The dielectric material 330 may for example include or consist of a resin, an adhesive, or another encapsulation material used in the art for encapsulating dice. The dielectric material 330 may be used for encapsulating and fixing the die into the carrier laminate 102, e.g. the PCB core layer, and in particular to fix the die 220 inside the recess 108 in the carrier laminate 102.

The dielectric material 330 may for example be dispensed, screen or stencil printed, or laminated (e.g., an Ajinomoto Boding Film (ABF)), and may for example include or consist of a Photo Imageable Dielectric (PID) or a liquid polyimide that may subsequently be cured.

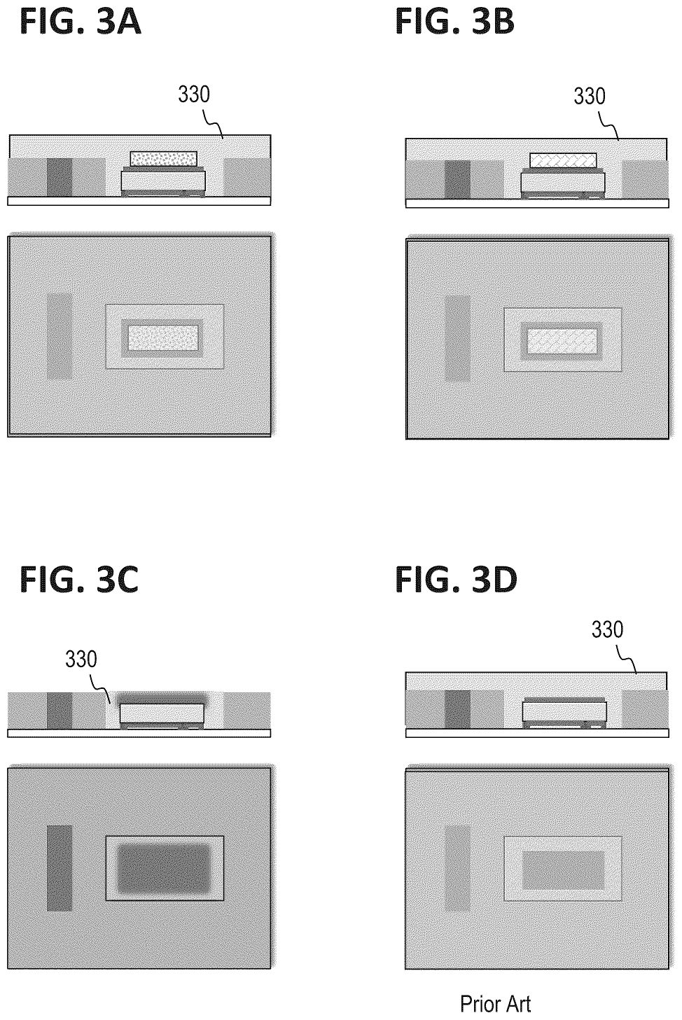

The dielectric material 330 may in various embodiments be applied to extend outside the recess 108. The dielectric material 330 may at least partially (e.g. fully) cover the top side of the die 220 (that faces away from the temporary carrier laminate 106), for example the layer 210, and/or a top side of the carrier laminate 106. Corresponding exemplary embodiments are shown in FIGS. 3A and 3B for the embodiments including the thick dielectric layer 210, 210a and the thick metal layer 210, 210b, respectively.

In various embodiments, the dielectric material 330 may be arranged essentially only inside the recess 108. An upper surface of the dielectric material may for example be essentially flush with the top surface of the carrier laminate 102. In a case where the die 220, 220c is slightly smaller than the depth of the recess 108, the layer 210, 210c may partially or completely be covered by a thin layer of dielectric material 330. A corresponding embodiment is illustrated in FIG. 3C.

In the prior art, as shown in FIG. 3D, a relatively large portion of the dielectric material 330 may be piled up above the die 200.

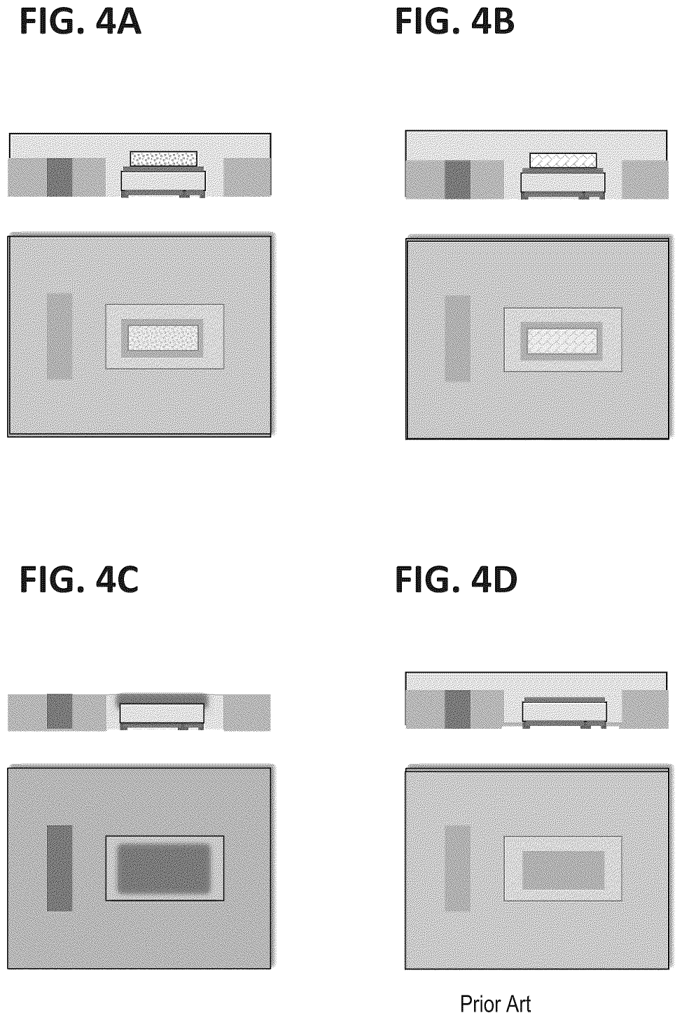

In various embodiments, the temporary carrier 106 may be removed at this stage of the process. Respective exemplary embodiments are illustrated in FIGS. 4A to 4C. In the prior art, the temporary carrier 106 may also be removed at this stage, which is illustrated in FIG. 4D. Alternatively, the temporary carrier 106 may be removed at a later stage.

The method of embedding the bare die 220 in the carrier laminate 102 in accordance with various embodiments further includes removing a portion of the dielectric material 330 that is on the layer 210.

The removing may for example include mechanical grinding, wet chemistry, e. g. etching, laser ablation, and/or optically assisted removal (e.g. light development and decomposition). The optically assisted removal may be used in conjunction with any type of layer 330 (e.g., the dielectric layer 330, 330a, the thick metal layer 330, 330b, and/or the thin metal layer 330, 330c), as long as a photoimageable dielectric (PID) is used as the dielectric material 330. In that case, litography may be used to open the die backside BS.

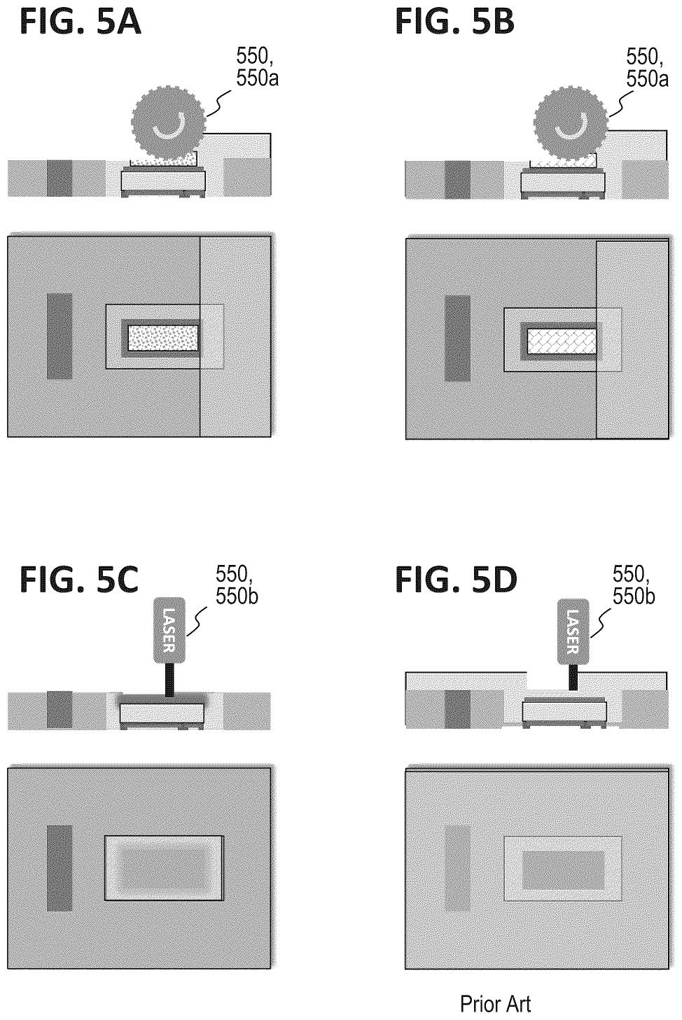

FIGS. 5A to 5C illustrate some of the exemplary embodiments.

For the removing of the relatively thick dielectric material 330, together with a portion of the (in this case dielectric) layer 310, 310a, which is illustrated in FIG. 5A, the mechanical grinding using a grinder 550, 550a may be suitable. However, in various embodiments, laser ablation (not shown) may for example be selected for removing the relatively thick dielectric material 330. After the removing process, a portion of the dielectric layer 310, 310a may remain and may be exposed at the top of the embedded die 1300.

For the removing of the relatively thick dielectric material 330, together with a portion of the (in this case metal) layer 310, 310b, which is illustrated in FIG. 5B, the mechanical grinding using a grinder 550, 550a may be suitable. However, in various embodiments, laser ablation (not shown) may for example be selected for removing the relatively thick dielectric material 330. After the removing process, a portion of the metal layer 310, 310a may remain and may be exposed at the top of the embedded die 1300.

For the removing of the relatively thin dielectric material 330, which is illustrated in FIG. 5C, the laser ablating may be suitable. Since the dielectric material 330 forms, if at all, only a thin layer on the thin metal layer 310, 310c the metal layer 310, 310c may be exposed at the top of the embedded die 1300 after the removing of the dielectric material 330. Also plasma etching may be applied if it is considered advantageous, since it requires only a short amount of processing time for the thin dielectric material layer 330.

In the prior art, as illustrated in FIG. 5D, a laser processing using e.g. a laser 500, 550b, is used.

In various embodiments, as described above in context with FIG. 5A, the grinding (or, optionally, the laser processing) may possibly not have led to an electrically conductive access to a chip contact that is exposed at an outside of the embedded die 1300. Thus, further processing may be required.

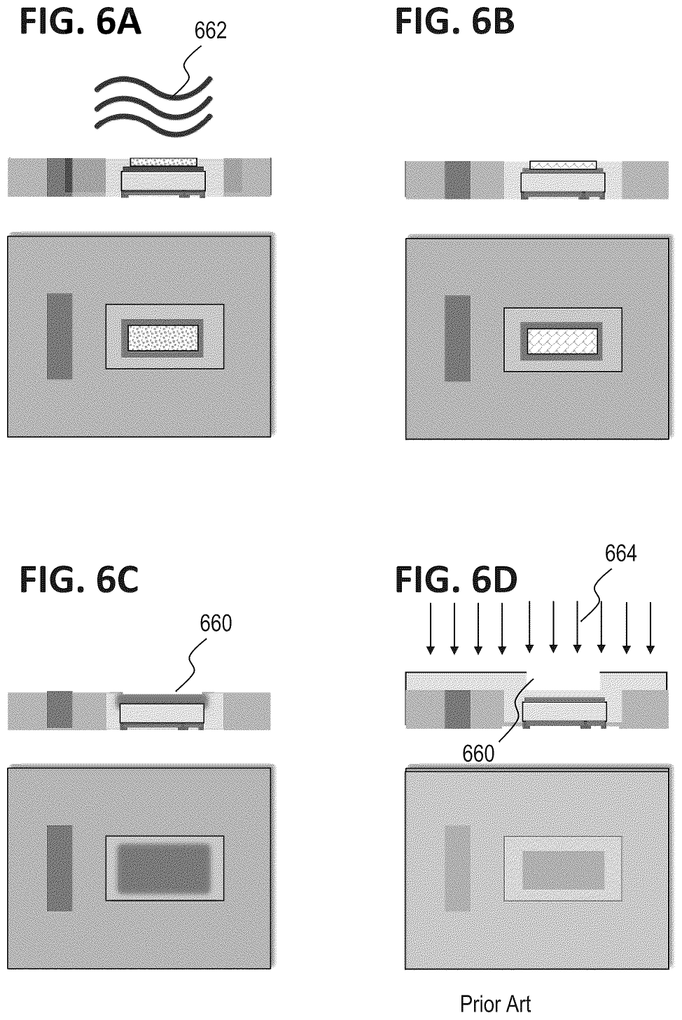

As shown in FIG. 6A, wet etching may be applied, as indicated by the wave-symbols 662 that indicate a liquid, in this case the etchant 662. Alternatively, for example dry etching or plasma etching may be used.

The etchant 662 may be chosen for selective etching of the (dielectric) layer 610, 610a. The etching may be continued until the metal layer 204 ist exposed.

The prior art process shown in FIG. 2D does not allow for such a treatment, since the whole top side is covered by the same material. Instead, as shown in FIG. 6D and indicated by the arrows 664, a dry etch process is used, which is expensive and time consuming.

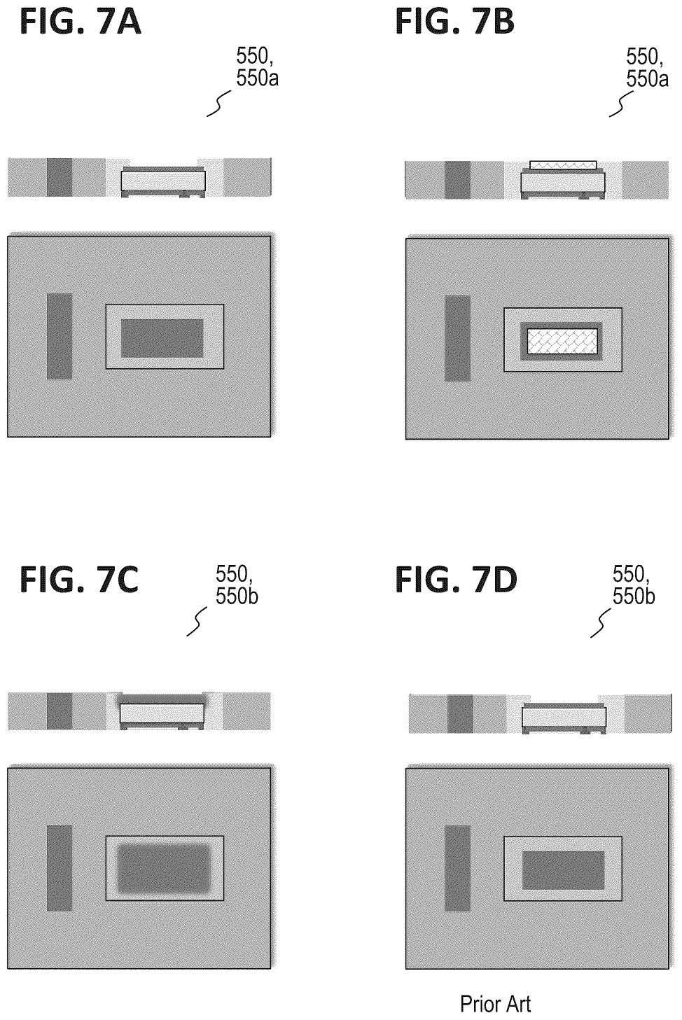

Results of the processes are shown in FIGS. 7A to 7D.

The method of embedding the bare die 220 in the carrier laminate 102 in accordance with various embodiments further includes depositing (e.g., using electroless plating, sputtering or ALD) a metal structure 880, 880a over at least a portion of the layer 310 and at least a portion of the carrier laminate 102.

In various embodiments, the metal structure 880, 880a may include copper, for example a copper seed layer. The metal structure 880, 880a may for example cover the whole surface of the layer 310 and the carrier laminate 102, or may be pre-structured using a masking process (not shown).

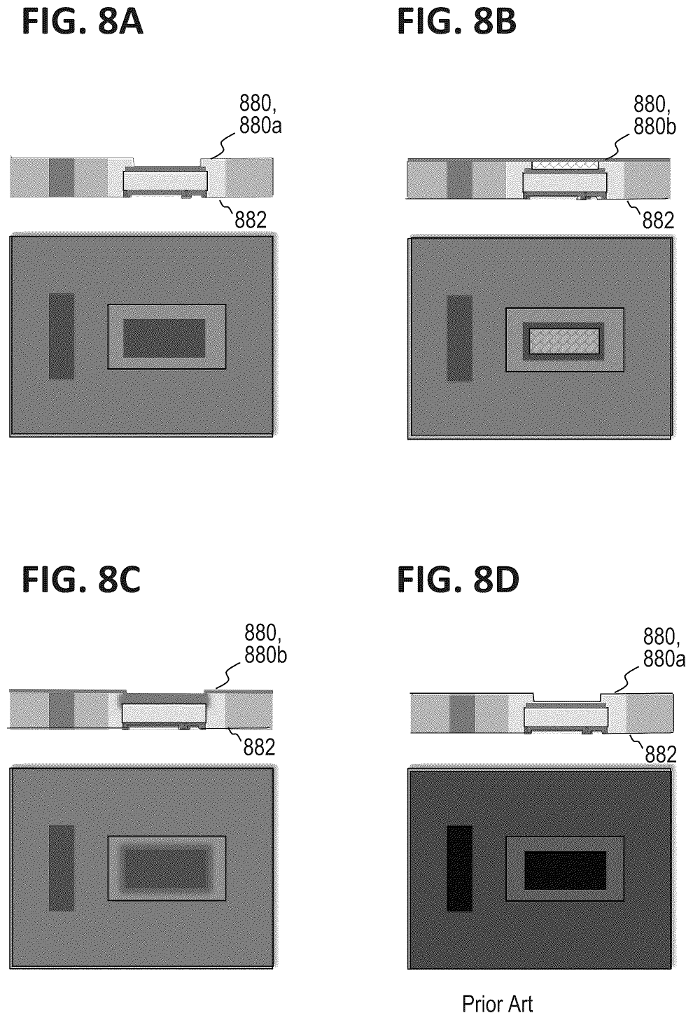

Corresponding embodiments are shown in FIGS. 8A to 8C.

In the prior art process shown in FIG. 8D, the metal structure 880, 880b is applied using a sputter deposition process, which is a non-standard PCB process and time consuming and expensive, compared to the electroless deposition process used in various embodiments.

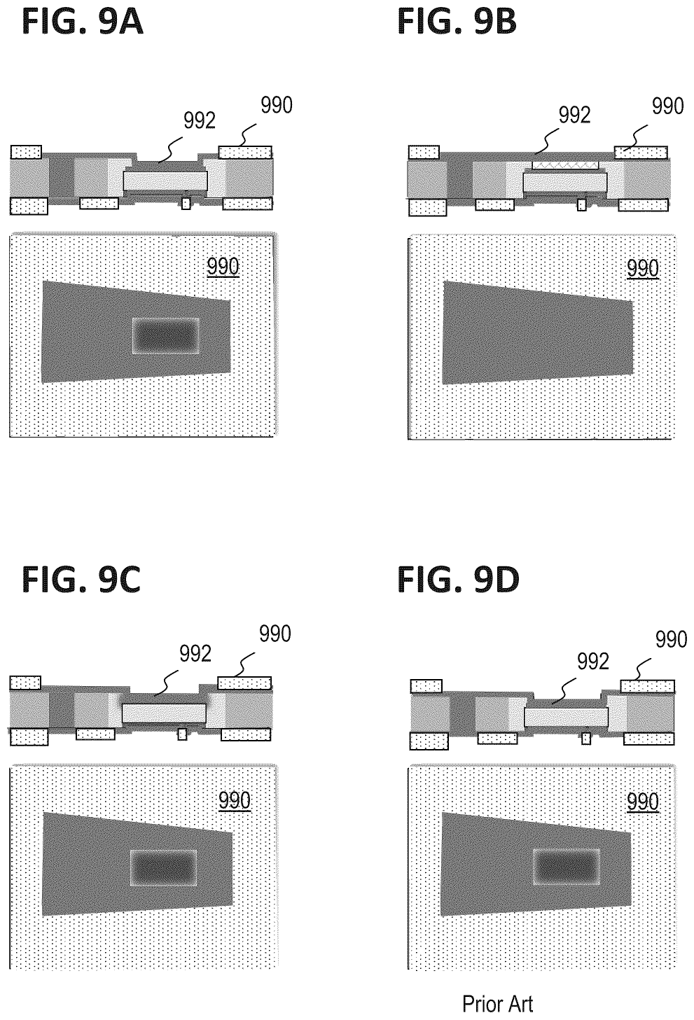

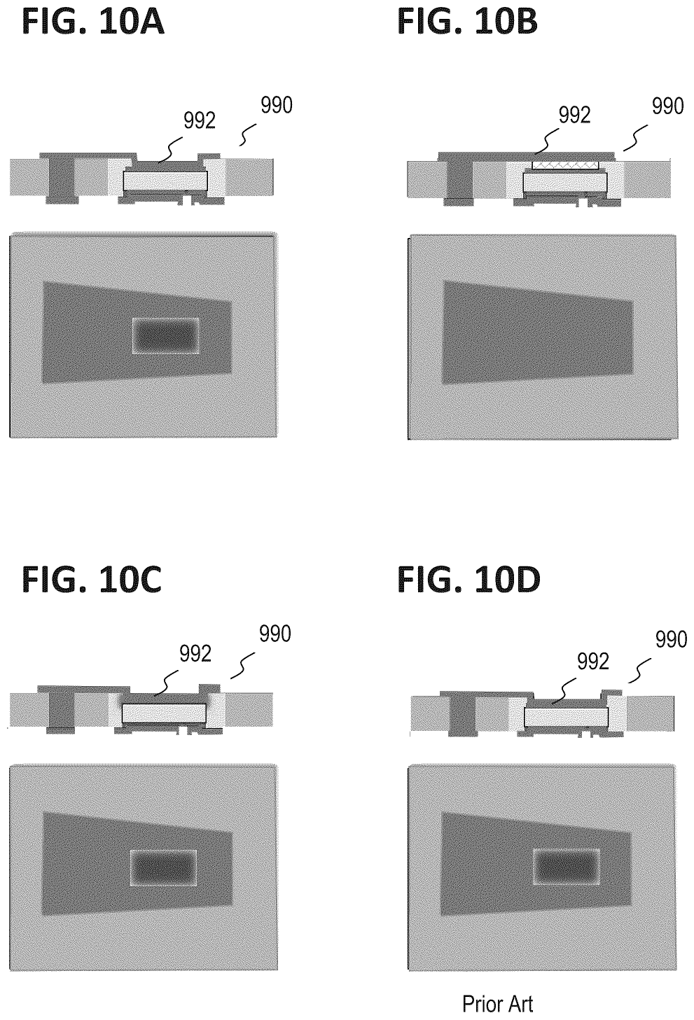

Subsequent processing proceeds essentially as known in the art. Thus, the features added during the processes illustrated in FIGS. 9A to 10A, 9B to 10B, and 9C to 10C for the embodiments are similar or identical to the features added according to the prior art as illustrated in FIGS. 9D to 10D.

In various embodiments, a further metal layer 992 may be plated onto the seed layer, for example using a standard electrolytic copper plating process. The further metal layer 992 may be formed as a structured layer, for example using a mask 990.

The plating process is illustrated in FIGS. 9A to 9C for the embodiments, and in FIG. 9D for the prior art.

It is to be noted that the processing leads to a slight dent or depression for the embodiments shown in FIGS. 9A and 9C, and in the prior art shown in FIG. 9D. This is indicated by the white-shaded rectangle in FIGS. 9A, 9C, and 9D. In contrast to this, the further metal layer 992 of the embodiment shown in FIG. 9B, in which the layer 310, 310b is the metal layer, does not show the dent, but rather a flat surface.

The further metal layer 992 may have a thickness of at least 5 μm.

In various embodiments, the metal structure 880, 880a may be removed in regions outside the further metal layer 992 by standard processes, e.g. etching. Similarly, the metal structure 880, 880b of the prior art is removed.

Exemplary embodiments are shown in FIGS. 10A to 10C. They may be similar or identical to the removal process of the prior art illustrated in FIG. 10D.

Further processing may proceed as known in the art, for example by adding a surface finish, dicing, forming a redistribution layer, etc.

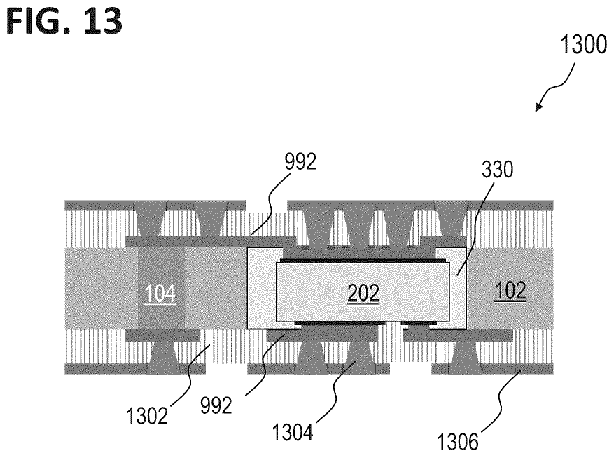

An exemplary embodiment of a finished carrier-embedded die 1300 is shown in FIG. 13.

In addition to the features described above in context with the method of various embodiments, the carrier-embedded die 1300 includes a redistribution layer 1306 attached over a dielectric material 1302, and contacted to the chip 202, or rather to the further metal layer 992, by vias 1304.

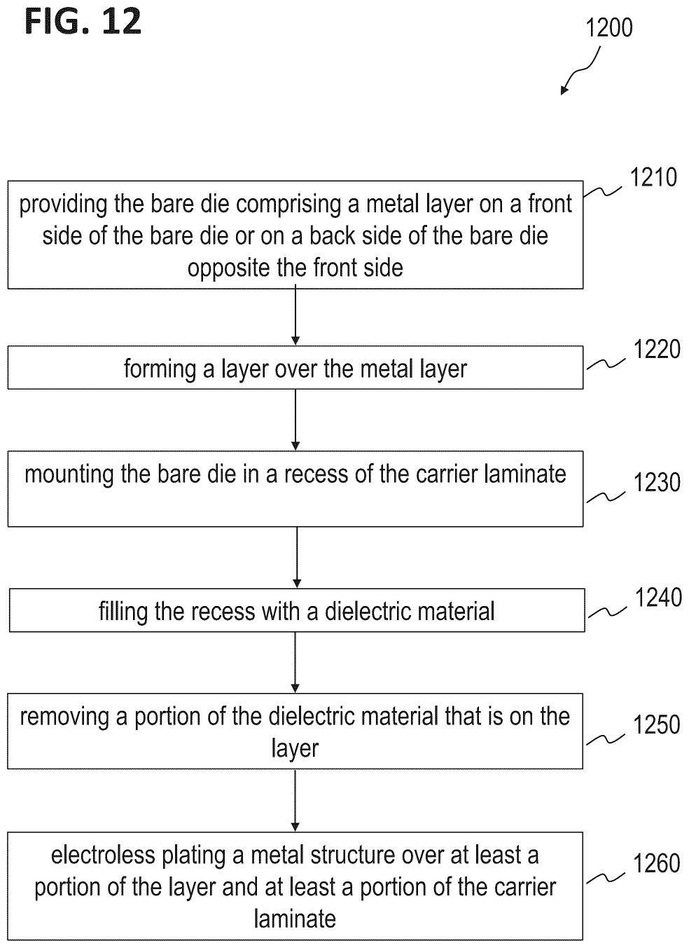

FIG. 12 shows a flow diagram 1200 of a method of embedding a bare die in a carrier laminate in accordance with various embodiments.

The method includes providing the bare die including a metal layer on a front side of the bare die or on a back side of the bare die opposite the front side (1210), forming a layer over the metal layer (1220), mounting the bare die in a recess of the carrier laminate with the layer facing an opening of the recess (1230), filling the recess with a dielectric material (1240), removing a portion of the dielectric material that is on the layer (1250), and electroless plating a metal structure over at least a portion of the layer and at least a portion of the carrier laminate (1260).

To summarize, additional pre-applied material (e.g., plated, laminated, printed, coated) may be applied to the embeddable object (e.g. embeddable die), and the pre-applied material is exposed later, during the PCB manufacturing, allowing more traditional or robust PCB processes known to the manufacturers be used.

The method could be used for open molded-packages as well.

Various examples will be illustrated in the following:

Example 1 is a method of embedding a bare die in a carrier laminate, the method including providing the bare die including a metal layer on a front side of the bare die or on a back side of the bare die opposite the front side, forming a layer over the metal layer, mounting the bare die in a recess of the carrier laminate with the layer facing an opening of the recess, filling the recess with a dielectric material, removing a portion of the dielectric material that is on the layer, and depositing a metal structure over at least a portion of the layer and at least a portion of the carrier laminate.

In Example 1a, the subject matter of Example 1 may optionally include that the depositing includes electroless plating, sputtering, or Atomic Layer Deposition (ALD).

In Example 2, the subject-matter of Example 1 may optionally include that the layer includes or consists of a dielectric layer or an electrically conductive layer.

In Example 3, the subject-matter of Example 1 or 2 may optionally include that the layer or the dielectric material includes or consists of a photoresist material.

In Example 4, the subject-matter of any of Examples 1 to 3 may optionally further include, after the removing a portion of the dielectric material that is on the layer, removing the layer.

In Example 5, the subject-matter of Example 4 may optionally include that the removing the layer includes or consists of wet etching, dry etching, plasma etching, or light deterioration.

In Example 6, the subject-matter of Example 1 or 2 may optionally include that the layer includes or consists of metal, optionally copper.

In Example 7, the subject-matter of any of Examples 1 to 6 may optionally include that a total thickness of the bare die including the layer is thicker than a depth of the recess.

In Example 8, the subject-matter of any of Examples 1 to 7 may optionally include that a thickness of the layer is larger than a thickness of the metal layer.

In Example 9, the subject-matter of any of Examples 1 to 8 may optionally include that a thickness of the layer is in a range from about 2 μm to about 30 μm.

In Example 10, the subject-matter of any of Examples 1 to 9 may optionally include that the forming the layer over the metal layer includes or consists of plating, laminating, printing and/or coating.

In Example 11, the subject-matter of any of Examples 1 to 10 may optionally include that the carrier is a printed circuit board.

In Example 12, the subject-matter of any of Examples 1 to 11 may optionally include that the arranging the dielectric material that fills the recess includes arranging the dielectric material to extend beyond the layer and to at least partially cover the layer.

In Example 13, the subject-matter of any of Examples 1 to 12 may optionally include that the removing a portion of the dielectric material that is on the layer includes grinding, laser ablation or light deterioration.

In Example 14, the subject-matter of any of Examples 1 to 13 may optionally include that the mounting the bare die in the recess includes arranging the bare die on a temporary carrier.

In Example 15, the subject-matter of Example 14 may optionally further include, after the arranging the dielectric, removing the temporary carrier.

In Example 16, the subject-matter of any of Examples 1 to 15 may optionally include that the bare die further includes a further metal layer on the other side of the bare die opposite the metal layer.

In Example 17, the subject-matter of Example 16 may optionally further include arranging a further layer over the further metal layer.

In Example 18, the subject-matter of Example 17 may optionally include that the further layer includes or consists of the same material as the layer.

In Example 19, the subject-matter of Example 1 may optionally include that the layer includes or consists of an electrically conductive layer formed by sputtered material, a thin-film or a nano-coating.

In Example 20, the subject-matter of Example 19 may optionally include that a thickness of the layer is smaller than a thickness of the metal layer.

In Example 21, the subject-matter of Example 19 or 20 may optionally include that a thickness of the layer is in a range from about 1 nm to about 2 μm.

In Example 22, the subject-matter of any of Examples 19 to 21 may optionally include that the layer is an atomic layer deposition (ALD) layer.

In Example 23, the subject-matter of Example 22 may optionally include that the ALD layer covers a plurality of sides of the bare die, optionally encapsulating the bare die.

In Example 24, the subject-matter of any of Examples 1 to 23 may optionally further include arranging a thick metal layer over the metal layer.

In Example 25, the subject-matter of Example 24 may optionally include that the arranging the thick metal layer includes or consists of electroless plating.

In Example 26, the subject-matter of any of Examples 1 to 25 may optionally include that the metal layer includes or consists of copper or aluminum.

In Example 27, the subject-matter of any of Examples 1 to 26 may optionally include that the dielectric material is a photosensitive resin.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of embedding a bare die in a carrier laminate, the method comprising:
providing the bare die comprising a metal layer on a front side of the bare die or on a back side of the bare die opposite the front side;
forming a layer over the metal layer;
mounting the bare die in a recess of the carrier laminate with the layer facing an opening of the recess;
filling the recess with a dielectric material;
removing a portion of the dielectric material that is on the layer;
depositing a metal structure over at least a portion of the layer and at least a portion of the carrier laminate.

2. The method of claim 1,
wherein the layer comprises or consists of a dielectric layer or an electrically conductive layer.

3. The method of claim 1,
wherein the layer or the dielectric material comprises or consists of a photoresist material.

4. The method of claim 1, further comprising:
after the removing a portion of the dielectric material that is on the layer, removing the layer.

5. The method of claim 4,
wherein the removing the layer comprises or consists of wet etching, dry etching, plasma etching, or light deterioration.

6. The method of claim 1,
wherein the layer comprises or consists of metal, optionally copper.

7. The method of claim 1,
wherein a total thickness of the bare die including the layer is thicker than a depth of the recess.

8. The method of claim 1,
wherein a thickness of the layer is larger than a thickness of the metal layer.

9. The method of claim 1,
wherein a thickness of the layer is in a range from about 2 μm to about 30 μm.

10. The method of claim 1,
wherein the forming the layer over the metal layer comprises or consists of plating, laminating, printing and/or coating.

11. The method of claim 1,
wherein the carrier is a printed circuit board.

12. The method of claim 1,
wherein the arranging the dielectric material that fills the recess comprises arranging the dielectric material to extend beyond the layer and to at least partially cover the layer.

13. The method of claim 1,
wherein the removing a portion of the dielectric material that is on the layer comprises grinding, laser ablation or light deterioration.

14. The method of claim 1,
wherein the mounting the bare die in the recess comprises arranging the bare die on a temporary carrier.

15. The method of claim 14, further comprising:
after the arranging the dielectric, removing the temporary carrier.

16. The method of claim 1,
wherein the bare die further comprises a further metal layer on the other side of the bare die opposite the metal layer.

17. The method of claim 16, further comprising:
arranging a further layer over the further metal layer.

18. The method of claim 17,
wherein the further layer comprises or consists of the same material as the layer.

19. The method of claim 1,
wherein the layer comprises or consists of an electrically conductive layer formed by sputtered material, a thin-film or a nano-coating.

20. The method of claim 19,
wherein a thickness of the layer is smaller than a thickness of the metal layer.

21. The method claim 19,
wherein a thickness of the layer is in a range from about 1 nm to about 2 μm.

22. The method of claim 19,
wherein the layer is an atomic layer deposition (ALD) layer.

23. The method of claim 22,
wherein the ALD layer covers a plurality of sides of the bare die, optionally encapsulating the bare die.

24. The method of claim 1, further comprising:
arranging a thick metal layer over the metal layer.

25. The method of claim 24,
wherein the arranging the thick metal layer comprises or consists of electroless plating

26. The method of claim 1,
wherein the metal layer comprises or consists of copper or aluminum.

27. The method of claim 1,
wherein the dielectric material is a photosensitive resin.
